(19) United States
(12) Patent Application Publication
(10) Pub. No.: US 2004/0121543 A1
(43) Pub. Date: Jun. 24, 2004

(54) Method of manufacturing semiconductor device

(75) Inventor: Yoshihiro Miyagawa, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/733,233

(22) Filed: Dec. 12, 2003

(30) Foreign Application Priority Data
Dec. 20, 2002 (JP) 2002-370025(P)
Oct. 6, 2003 (JP) 2003-347115(P)

(51) Int. Cl. H01L 21/31

(52) U.S. Cl. 438/261; 438/287; 438/308; 438/770

(57) ABSTRACT

First, an first insulating film is formed along surfaces of a plurality of combinations of an gate electrode and an gate insulating films, and a semiconductor substrate, respectively. Then, on the first insulating film, an second insulating film different from the first insulating film is formed. The steps of forming the first insulating film and forming the second insulating film are alternately repeated until a concave formed by the surface of an later insulating film, which is a film formed later out of the first insulating film and the second insulating film, is positioned above the upper surface of the gate electrode. Thereafter, an third insulating film is formed on the later insulating film. Thus, a semiconductor device with high reliability can be obtained by improving a state of the insulating film formed between the gate electrodes.

### BACKGROUND OF THE INVENTION

1. Field of the Invention

The present invention relates to a method of manufacturing a semiconductor device in which a space between gate electrodes is filled with an insulating film.

2. Description of the Background Art

In general, when a space between gate electrodes is very narrow, a BPSG (Boro-Phospho-Silicate Glass) film or an HDPCVD film formed with a High-Density-Plasma Chemical Vapor Deposition using high-density plasma serves as an insulating film for filling such a space.

In addition, a method for reflowing the BPSG film or the HDPCVD film by performing a thermal processing to such a film so that the space between the gate electrodes is appropriately filled with the film is employed.

A conventional semiconductor device has a distance between the gate electrodes of not smaller than 0.1 μm, and has an aspect ratio of the space therebetween of not larger than 3. In addition, a property of the conventional semiconductor device is not adversely affected by a high-temperature process (furnace process at 850° C. or higher, or lamp annealing at 950° C. or higher) in a thermal processing step after deposition of the BPSG film or the HDPCVD film. Therefore, in the conventional semiconductor device, a defect is not produced in filling the space between the gate electrodes. In other words, in a manufacturing process of the conventional semiconductor device, a void created in forming the BPSG film or the HDPCVD film can be eliminated through the high-temperature process after the film is deposited.

In addition, in forming a film with O₃/TEOS (Tetra Ethyl Ortho Silicate) atmospheric pressure CVD reaction, a type and a surface state of a film that underlies a deposited film considerably affect a property of the deposited film. Therefore, in order to achieve isotropic or normal film-forming, a processing such as wet etching, plasma processing, annealing, or the like is performed before film-forming. In doing so, a quality of the surface of an underlying layer is altered. Consequently, the BPSG film or the HDPCVD film is formed on the underlying layer, while an adverse effect on the formed film by the state of the underlying layer is suppressed.

For a semiconductor device of the recent days, smaller size, higher density and higher aspect ratio have been demanded, while a lower temperature for the thermal processing for reflowing the insulating film such as the BPSG film has been desired. Therefore, in some cases, a space between the gate electrodes may not sufficiently be filled. In such a case, a short-circuit occurs between two contact plugs which are provided between the gate electrodes and is respectively connected to one source/drain region and another source/drain region, and the gate electrode. This will produce a large amount of leak current, and results in abnormal operation of a transistor.

For example, a TEOS film formed with LP (Low Pressure)-CVD, and the BPSG film formed with SiH₄/O₂-based atmospheric pressure CVD or TEOS/O₃-based CVD are used to form an insulating film in the space between the gate electrodes (the space therebetween is narrow, and has a high aspect ratio and a deformed shape). The insulating film tends to be formed in an overhang shape at the upper portion of the gate electrode, and does not provide sufficient coverage of the space between the gate electrodes. Therefore, a very large void is left in the insulating film.

In order to eliminate the large void, a thermal processing step is needed after the insulating film is formed, for at least 15 minutes at 850° C. when using the furnace process, and for at least 30 seconds at 950° C. when using the lamp annealing.

In the thermal processing at the above-mentioned temperature, however, a thermal budget (a total capacity of heat applied to the semiconductor device in a manufacturing process thereof) is extremely large. As a result, a property of the transistor is deteriorated. Therefore, it becomes necessary to lower the temperature for the thermal processing of the insulating film filling the space between the gate electrodes, or to eliminate reflowing step of the insulating film.

When the BPSG film serves as the insulating film filling the space between the gate electrodes, a reflowing step property of the BPSG film is improved by increasing a concentration of an impurity in the BPSG film. Therefore, the temperature for the thermal processing for the BPSG film can be lowered (20 to 30° C.).

On the other hand, when the thermal processing for the BPSG film is performed after a contact hole is opened in the BPSG film, the contact hole may slide. In addition, resulting from B (boron isotope¹⁰B), a soft error in a system may occur in the semiconductor device.

Moreover, because P and B contained in the BPSG film deposit (precipitate) as a foreign matter, a subsequent step for interconnection may not be properly performed. Accordingly, the interconnection is disconnected, and the achievement of the BPSG film with a higher concentration of B and P and even the use thereof could be difficult.

In addition, the BPSG film with high impurity concentration can be reflowed with a low temperature. When the thermal processing of the BPSG film is not sufficient, however, a foreign matter is produced from the BPSG film due to deterioration of a quality thereof in a section where the BPSG film is exposed. Accordingly, the interconnection is disconnected, and a defect is produced in the semiconductor device.

On the other hand, the quality of the insulating film formed with O₃/TEOS atmospheric pressure CVD reaction is considerably affected by the surface state (such as a type and material of the film, and a condition of contamination) of the underlying layer on which the film is deposited. Therefore, in order to process the surface of the underlying layer for changing it from hydrophilic to hydrophobic, a processing such as wet etching, plasma processing, annealing, or the like can be performed. Therefore, setting of a storage time from a preceding process step is required, the number of process steps is increased, or an operation of a manufacturing line is restricted.

### SUMMARY OF THE INVENTION

An object of the present invention is to provide a method of manufacturing a semiconductor device with high reliability, by improving a state of an insulating film formed between gate electrodes.

A method according to the present invention is used for manufacturing a semiconductor device in which a plurality of combinations of a gate electrode and a gate insulating film are formed so as to extend in parallel on a semiconductor substrate. The method includes the steps of forming a first insulating film along surfaces of the plurality of combinations of the gate electrode and the gate insulating film, and the semiconductor substrate, and forming a second insulating film different from the first insulating film on the first insulating film. In the manufacturing method, the steps of forming the first insulating film and forming the second insulating film are alternately repeated.

According to the above-described manufacturing method, by improving the state of the insulating film formed between the gate electrodes, a semiconductor device with high reliability can be manufactured.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 4 illustrate a method of manufacturing a semiconductor device in an embodiment.

### DESCRIPTION OF THE PREFERRED EMBODIMENTS

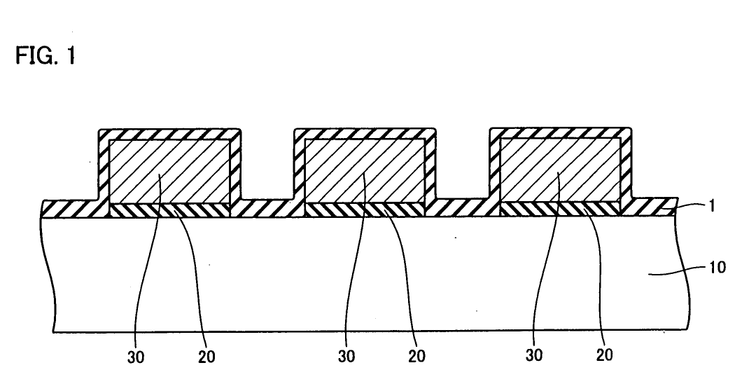

In the following, a semiconductor device according to the embodiment of the present invention will be described with reference to FIGS. 1 to 4.

As shown in FIG. 1, in the method of manufacturing the semiconductor device according to the present embodiment, a gate insulating film 20 is initially formed on a semiconductor substrate 10. Then, a gate electrode 30 is formed on gate insulating film 20. Thereafter, an insulating film 1 is formed so as to extend along the surface of semiconductor substrate 10, the side surfaces of gate insulating film 20, and the side surfaces and the upper surface of gate electrode 30 respectively. Thus, a structure shown in FIG. 1 can be obtained. In the step of forming insulating film 1, a chemical vapor reaction and a surface reaction are used to deposit insulating film 1 composed of USG (Undoped Silicate Glass) to a thickness of 3 to 5% of a distance between gate electrodes 30. In other words, insulating film 1 attains a thickness of 3 to 5% of the distance between gate electrode 30.

An object of the step of forming insulating film 1 (predeposition) is to alter a quality of the surface of semiconductor substrate 10 serving as an underlying layer, the side surfaces of gate insulating film 20 serving as an underlying layer, and the side surfaces and the upper surface of gate electrode 30 serving as an underlying layer. Therefore, it is effective to form insulating film 1 in an atmosphere containing O₃ of a low concentration.

In addition, if insulating film 1 is formed to a thickness of not smaller than 5% of the distance between gate electrodes 30, insulating film 1 formed between gate electrodes 30 tends to be formed in an overhang shape. In addition, once the insulating film between the gate electrodes is formed in the overhang shape, the void is surely formed in an insulating film 2 formed between gate electrodes 30 in a subsequent step of film-forming. Therefore, the thickness of insulating film 1 is desirably in a range of 3 to 5% of the distance between gate electrodes 30.

Here, a detailed condition for forming insulating film 1 is shown below.

A concentration of ozone (O₃) in the atmosphere for film-forming is set to 0 to 3 wt %. In addition, a molar ratio of O₃/TEOS in the atmosphere is set to 0 to 3.0. A temperature for film-forming is set to 450 to 550° C. A pressure for film-forming is set to 600 to 200 Torr (798 to 266 hPa). With regard to a type of a carrier gas, He/N₂ mixed gas is used as an example of an inert gas.

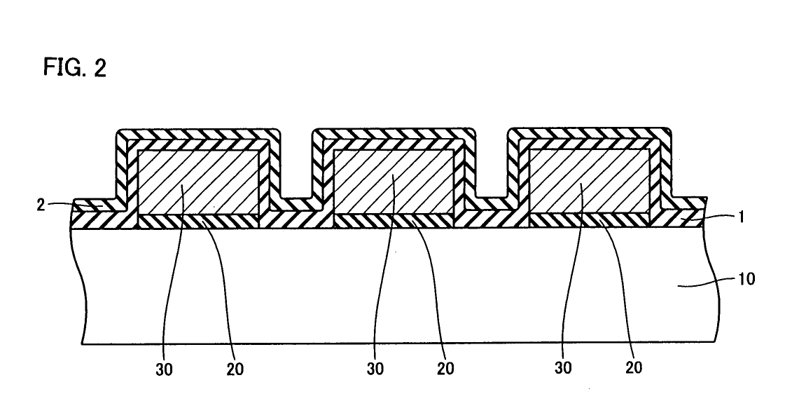

After insulating film 1 described above is formed, the step of forming insulating film 2 along the surface of insulating film 1 (main deposition) is performed, as shown in FIG. 2. Unlike forming insulating film 1, the concentration of ozone (O₃) in the atmosphere for film-forming is changed to 8.0 to 17.0 wt % in forming insulating film 2. The reason for changing ozone (O₃) concentration is because a precursor with a large molecular weight is formed on the surface of, or in the vicinity of the surface of, the underlying layer. As the precursor with a large molecular weight has fluidity, insulating film 2 formed on insulating film 1 is not formed in an overhang shape in the vicinity of the upper side portion of gate electrode 30.

Here, insulating film 2 is composed of BPSG, PSG, BSG, or USG. A condition for forming insulating film 2 is shown below.

The temperature for film-forming is set to 450 to 550° C. The pressure for film-forming is set to 600 to 200 Torr (798 to 266 hPa). A total concentration of an impurity composed of at least one of P and B is set to not larger than 15 wt %. In addition, the molar ratio of O₃/TEOS is set to 3.0 to. 15.0. With regard to a type of a carrier gas, He gas or He/N₂ mixed gas is used as an example of an inert gas. Moreover, insulating film 2 has a film thickness of 5 to 10% of the distance between gate electrodes 30.

In forming insulating film 2, a gas such as TEOS, TEB (Triethyl Borate: (C₂H₅O)₃B), TEPO (Triethyl Phosphate: (C₂H₅O)₃PO), and O₃ is supplied into a reaction chamber as a reaction gas for forming insulating film 2.

Further, after the step of forming insulating film 2 is completed, supply of the reaction gas for depositing insulating film 2 is stopped, and O₂ instead of O₃ is supplied to the reaction chamber so as to keep the pressure in the reaction chamber constant. Accordingly, a gas other than TEOS, that is, TEB or TEPO, is run through a vent line (an emission line) so as not to enter the reaction chamber, or supply of such a gas (TEB or TEPO) is stopped.

Alternatively, O₃ may be continuously supplied into the reaction chamber so as to keep the pressure in the reaction chamber constant, and a TEOS, TEB and TEPO gases may be run through the vent line. In this method, the supply of the TEB and TEPO gas to the reaction chamber may be stopped.

In this step, by suspending the continuous main deposition, insulating film 2 is self-planarized (migration) along an surface of the underlying layer after insulating film 2 is deposited thereon. For sufficient self-planarization, the main deposition should be suspended for at least 15 seconds.

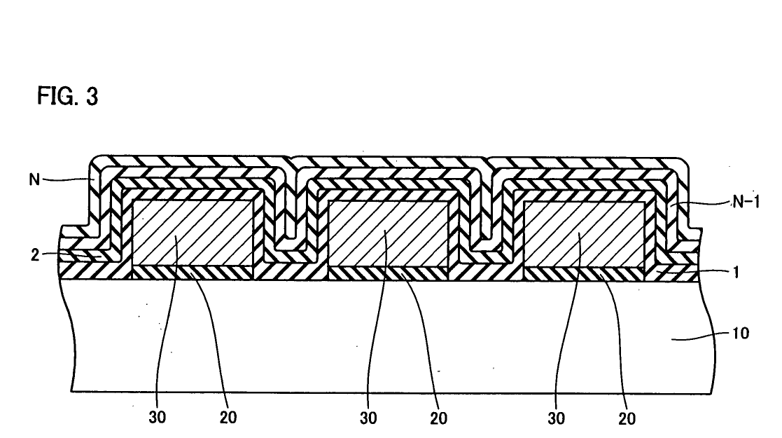

The steps of predeposition and main deposition described above are repeated until the space between gate electrodes 30 is completely filled (void free). In other words, the steps of forming insulating film 1 and forming insulating film 2 are alternately repeated until the bottom surface of a concave formed by the surface of insulating film 2 is positioned above the upper surface of gate electrode 30. Thus, as shown in FIG. 3, an insulating film N is formed on an insulating film N−1. Here, N is a natural number.

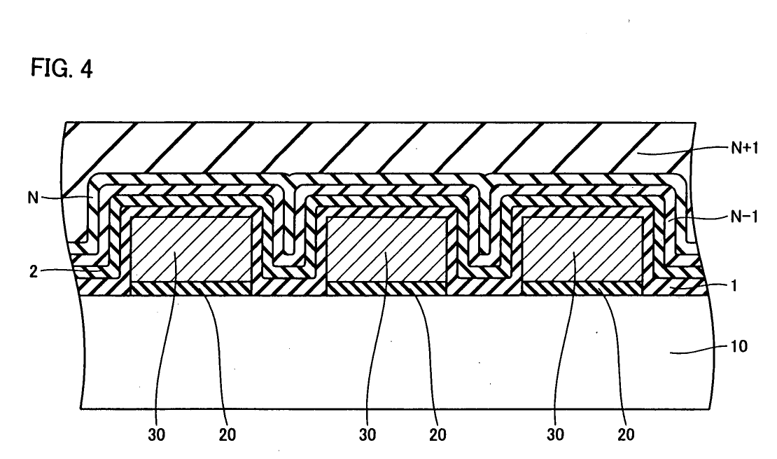

In addition, in FIG. 3 and FIG. 4 described below, though insulating film N−1 is formed on insulating film 2, this illustration is due to restriction in the drawings. Depending on a relation of a distance of between gate electrodes 30 and a film thickness of insulating films 1 and 2, several layers of insulating films can further be included between insulating film 2 and insulating film N−1.

Finally, after the space between gate electrodes 30 is completely filled, an insulating film N+1 composed of USG (Undoped Silicate Glass) of a thickness of not larger than 1.5 μm is formed on insulating film N as shown in FIG. 4 under a condition as shown below.

The pressure for film-forming is set to not larger than 200 Torr (266 hPa) so as to attain a large film-forming rate. The temperature for film-forming, the concentration of O₃, and the type of the carrier gas (He/N₂ mixed gas as an example of the inert gas), and the molar ratio of O₃/TEOS are the same as with insulating film 2.

According to the method of manufacturing the semiconductor device of the present embodiment as described above, by repeating predeposition and main deposition, an effect as set forth below can be obtained. Even if the space between gate electrodes 30 is narrow, the insulating film can sufficiently fill the space between gate electrodes. In addition, according to the above-described manufacturing method, reflowing is not needed in the step of forming insulating films 1 and 2. Therefore, the thermal budget in the manufacturing process of the semiconductor device can be suppressed, and a performance of the semiconductor device can be improved.

Further, since the step for altering the quality of the surface of the underlying layer, such as wet etching, plasma processing, annealing, or the like, is not necessary, the number of process steps in manufacturing can be reduced. In addition, by using the USG film as the final deposition film, generation of a huge foreign matter (a chip killer foreign matter) specific to the BPSG film after the thermal processing can be suppressed. Therefore, a possibility of generation of a defect due to the huge foreign matter can be lowered in the subsequent steps. Thus, yield of the semiconductor device can be improved.

Moreover, according to the manufacturing method described above, by reducing usage of an impurity such as B, the soft error in the system due to the impurity such as B (Boron isotope¹⁰B) can be reduced. Consequently, the yield and quality of the semiconductor device can be improved.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a semiconductor device in which a plurality of combinations of a gate electrode and a gate insulating film are formed so as to extend in parallel on a semiconductor substrate, comprising the steps of:
forming a first insulating film along surfaces of said plurality of combinations of the gate electrode and the gate insulating film, and said semiconductor substrate, respectively; and
forming a second insulating film different from said first insulating film on said first insulating film; wherein
the steps of forming said first insulating film and forming said second insulating film are alternately repeated.

2. The method of manufacturing a semiconductor device according to claim 1, wherein
said first insulating film is formed under a condition that
a concentration of O₃ is set to 0 to 3.0 wt %,
a molar ratio of O₃/TEOS is set to at most 3.0,
a temperature for film-forming is set to 450 to 550° C.,
a pressure for film-forming is set to 798 to 266 hPa, and
an inert gas is used as a carrier gas.

3. The method of manufacturing a semiconductor device according to claim 1, wherein
said first insulating film is composed of USG, and
said second insulating film is composed of one substance selected from a group consisting of BPSG, PSG, BSG, and USG.

4. The method of manufacturing a semiconductor device according to claim 1, wherein
said first insulating film has a film thickness of 3 to 5% of a distance between the gate electrodes of adjacent two of said combinations.

5. The method of manufacturing a semiconductor device according to claim 1, wherein
the step of forming said second insulating film is performed under a condition that
a concentration of O₃ is set to 8.0 to 17.0 wt %,
a molar ratio of O₃/TEOS is set to 3.0 to 15.0,
a temperature for film-forming is set to 450 to 550° C.,
a pressure for film-forming is set to 798 to 266 hPa,
a total concentration of an impurity composed of at least one of P
and B is set to at most 15 wt %, and
an inert gas is used as a carrier gas.

6. The method of manufacturing a semiconductor device according to claim 1, wherein
said second insulating film has a film thickness of 5 to 10% of the distance between the gate electrodes of adjacent two of said combinations.

7. The method of manufacturing a semiconductor device according to claim 1, wherein
the steps of forming said first insulating film and forming said second insulating film are repeated until a concave formed by said first insulating film or said second insulating film in a space between the gate electrodes of adjacent two of said combinations is positioned above the upper surface of said gate electrode.

8. The method of manufacturing a semiconductor device according to claim 1, wherein
said second insulating film is deposited using a reaction gas consisting of a plurality of kinds of gases which flows into a chamber, and
after the step of depositing said second insulating film, a supply into said chamber of at least one of said plurality of kinds of gases is stopped, and a gas which is different from said reaction gas and does not cause a reaction for deposition of said second insulating film flows into said chamber so that a pressure in said chamber is maintained constant.

9. The method of manufacturing a semiconductor device according to claim 1, wherein
said second insulating film is deposited using a reaction gas consisting of a plurality of kinds of gases which flows into a chamber, and
after the step of depositing said second insulating film, a supply into said chamber of at least one of said plurality of kinds of gases is stopped, and at least one of said plurality of kinds of gases continues to flow into said chamber so that a pressure in said chamber is maintained constant.

10. The method of manufacturing a semiconductor device according to claim 1, wherein
said second insulating film is deposited using a reaction gas consisting of a plurality of kinds of gases which flows into a chamber, and
after the step of depositing said second insulating film, at least one of said plurality of kinds of gases flows through a vent line to the outside of said chamber, and a gas which is different from said reaction gas and does not cause a reaction for deposition of said second insulating film flows into said chamber so that a pressure in said chamber is maintained constant.

11. The method of manufacturing a semiconductor device according to claim 1, wherein
said second insulating film is deposited using a reaction gas consisting of a plurality of kinds of gases which flows into a chamber, and
after the step of depositing said second insulating film at least one of said plurality of kinds of gases flows through a vent line to the outside of said chamber, and at least one of said plurality of kinds of gases continues to flow into said chamber so that a pressure in said chamber is maintained constant.

12. The method of manufacturing a semiconductor device according to claim 1, wherein
after the steps of forming said first insulating film and forming said second insulating film are repeated, a third insulating film is formed on a film formed later out of said first insulating film and said second insulating film.

13. The method of manufacturing a semiconductor device according to claim 12, wherein
the step of forming said third insulating film is performed under a condition that
a pressure for film-forming is set to at most 266 hPa,
a concentration of O₃ is set to 8.0 to 17.0 wt %,
a temperature for film-forming is set to 450 to 550° C., and
an inert gas is used as a carrier gas.

14. The method of manufacturing a semiconductor device according to claim 12, wherein
said third insulating film has a film thickness of at most 1.5 μm.

15. The method of manufacturing a semiconductor device according to claim 12, wherein
said third insulating film is a USG film.
